(19) United States
(12) Patent Application Publication
(10) Pub. No.: US 2012/0068350 A1
(43) Pub. Date: Mar. 22, 2012

(54) SEMICONDUCTOR PACKAGES, ELECTRONIC DEVICES AND ELECTRONIC SYSTEMS EMPLOYING THE SAME

(75) Inventors: Tong-Suk Kim, Hwaseong-si (KR); Woo-Jae Kim, Hwaseong-si (KR); Yun-Seok Choi, Hwaseong-si (KR); Seon-Hyang You, Dajeon (KR)

(73) Assignee: Samsung Electronics Co., Ltd., Suwon-si (KR)

(21) Appl. No.: 13/237,189

(22) Filed: Sep. 20, 2011

(30) Foreign Application Priority Data
Sep. 20, 2010 (KR) 10-2010-0092615

(51) Int. Cl. H01L 23/52

(52) U.S. Cl. 257/773; 257/E23.141

(57) ABSTRACT

A semiconductor package, an electronic device, and an electronic system employing the same are provided. The semiconductor package includes a printed circuit board (PCB) and a semiconductor chip structure. A first PCB land region is provided on a first surface of the PCB. A plurality of first chip land regions are provided on a first surface of the semiconductor chip structure which faces the first surface of the PCB. A first connection structure for electrically connecting the first PCB land region to the plurality of first chip land regions is provided.

### CROSS-REFERENCE TO RELATED APPLICATIONS

This application claims priority under 35 U.S.C. §119 to Korean Patent Application No. 10-2010-0092615 filed on Sep. 20, 2010, the disclosure of which is hereby incorporated by reference in its entirety.

### BACKGROUND OF THE INVENTION

1. Field of the Invention

Embodiments of the inventive concept relate to semiconductor packages, electronic devices, and electronic systems employing the same.

2. Description of the Related Art

Semiconductor devices may be included in electronic systems in the form of a package.

### SUMMARY OF THE INVENTION

Embodiments of the inventive concept provide a semiconductor package structure capable of preventing defects such as cracks from occurring in a conductive connection structure which electrically connects a printed circuit board (PCB) to a semiconductor chip structure.

Other embodiments of the inventive concept provide an electronic device including a conductive connection structure for electrically connecting one lower region to a plurality of upper regions.

Still other embodiments of the inventive concept provide an electronic system employing a semiconductor package structure including a conductive connection structure with improved reliability and endurance which electrically connects a PCB and a semiconductor chip structure.

Additional aspects and advantages of the present general inventive concept will be set forth in part in the description which follows and, in part, will be obvious from the description, or may be learned by practice of the general inventive concept

The foregoing and/or other aspects and utilities of the inventive concept may be achieved by providing an electronic device including a package substrate and a semiconductor chip structure. A first lower region and a second lower region are provided on a first surface of the package substrate. A plurality of first upper regions and a second upper region are provided on a first surface of the semiconductor chip structure which faces the first surface of the package substrate. First and second connection structures are disposed between the first surface of the package substrate and the first surface of the semiconductor chip structure. The first connection structure which electrically connects the first lower region to the plurality of first upper regions is provided. The second connection structure which electrically connects the second lower region to the second upper region.

The connection structure may include a solder material.

Each of the plurality of first upper regions may have a smaller flat area than the first lower region.

The package substrate may include a lower conductive pattern provided on the first surface thereof, and a lower insulating material layer which covers the first surface thereof and has a lower openings exposing a predetermined regions of the lower conductive pattern. The lower conductive pattern exposed by the lower openings may be defined as the first and second lower regions.

The semiconductor chip structure may include upper conductive patterns provided on the first substrate thereof, and an upper insulating material layer which covers the first surface thereof and has upper openings exposing the upper conductive patterns. The upper conductive patterns exposed by the upper openings may be defined as the first and second upper regions.

The first lower region may have a larger flat area than the second lower region.

The first connection structure may have a larger width than the second connection structure.

The package substrate may have a larger flat area than the semiconductor chip structure.

The electronic device may further include a semiconductor package structure provided on the package substrate to cover the semiconductor chip structure, and a third connection structure configured to electrically connect the semiconductor package structure to the package substrate.

The package substrate may further include a third lower region provided on the first surface thereof to be spaced apart from the first and second lower regions, and the third lower region may be electrically connected to the third connection structure.

The package substrate may further include solder balls provided on a second surface thereof which is opposite to the first surface thereof.

The package substrate may include a PCB and the semiconductor chip structure may include a non-memory semiconductor chip. The semiconductor package structure may include a semiconductor memory chip.

The foregoing and/or other aspects and utilities of the inventive concept may also be achieved by providing a semiconductor package structure including a PCB and a semiconductor chip structure. A first PCB land region and a second PCB land region are provided on a first surface of the PCB. A plurality of first chip land regions and a second chip land region are provided on a first surface of the semiconductor chip structure which faces the first surface of the PCB. The first connection structure configured to electrically connect the first PCB land region to the plurality of first chip land regions is provided.

The second connection structure configured to electrically connect the second PCB land region to the second chip land region.

The first and second connection structures may have different widths from each other.

The first PCB land region may include a bending portion or any one of circular, elliptical, triangular and polygonal shapes.

The foregoing and/or other aspects and utilities of the inventive concept may also be achieved by providing an electronic system including a display unit; and a semiconductor package structure. The semiconductor package structure includes a first PCB land region provided on a first surface of a PCB, a plurality of first chip land regions provided on a first surface of a semiconductor chip structure which faces the first surface of the PCB, and a first connection structure configured to electrically connect the first PCB land region to the plurality of first chip land regions.

The semiconductor package structure may further includes a second PCB land region provided on the first surface of the PCB and having a smaller flat area than the first PCB land region, a second chip land region provided on the first surface of the semiconductor chip structure, and a second connection structure configured to electrically connect the second PCB land region to the second chip land region.

The semiconductor package structure may further include an upper semiconductor package provided on the PCB and configured to cover the semiconductor chip structure, and a third connection structure configured to electrically connect the upper semiconductor package to the PCB.

The electronic system may further include a body and a power unit configured to supply a voltage to the semiconductor package structure and the display unit. The semiconductor package structure may be provided in the body, and the display unit may be provided in the body or on a surface of the body.

The foregoing and/or other aspects and utilities of the inventive concept, may also be achieved by providing a semiconductor package structure including an electronic device as a first semiconductor package, the electronic device including a lower substrate having a first surface and a first lower region provided on the first surface, an upper substrate having a first semiconductor chip and a first surface disposed to face the first surface of the lower substrate and having a plurality of first upper regions provided on the first surface of the upper substrate, and a connection structure disposed between the first surfaces of the lower and upper substrates to electrically connect the first lower region to the plurality of first upper regions; a second semiconductor package having a second semiconductor chip to be connected to the first semiconductor package; and another connection structure to connect the second semiconductor package to another lower region of the first surface of the lower substrate.

The semiconductor package structure may further include a second connection structure disposed to connect a second lower region of the first surface of the lower region and a second upper region of the first surface of the upper substrate.

The number of the first lower region of the lower substrate may be different from the number of the plurality of the first upper regions, and the number of the second lower region may be same as the number of the second upper region.

An area of the first lower region of the lower substrate may be larger than a sum of areas of the plurality of the first upper regions.

The first connection structure, the second connection structure, and the another connection structure may be disposed in order from a center portion of the lower substrate or the upper substrate.

The first connection structure may be a power transmission terminal, and the another connection structure may be a signal or data transmission terminal.

The first lower region may include a plurality of sub-first lower regions, each of the first upper regions may include a plurality of sub-first upper regions, and the connection structure may include a plurality of sub-connection structures to connect each sub-first lower region to the plurality of sub-first upper regions.

Each of the sub-first lower regions may have an area larger than a sum of areas of the plurality of sub-first upper regions.

The foregoing and/or other aspects and utilities of the inventive concept may also be achieved by providing an electronic system including a semiconductor package structure having an electronic device as a first semiconductor package. The electronic device may include a lower substrate having a first surface and a first lower region provided on the first surface, an upper substrate having a semiconductor chip and a first surface disposed to face the first surface of the lower substrate and having a plurality of first upper regions provided on the first surface of the upper substrate, and a connection structure disposed between the first surfaces of the lower and upper substrates to electrically connect the first lower region to the plurality of first upper regions. The semiconductor package may further include a second semiconductor package having a second semiconductor to be connected to the first semiconductor package, and another connection structure to connect the second semiconductor package to another lower region of the first surface of the lower substrate. The semiconductor package may further include a function unit connected to the semiconductor package to process data of the semiconductor package and to communicate with an external apparatus to transmit or receive the data.

The foregoing and/or other aspects and utilities of the inventive concept, may also be achieved by providing an electronic device including a lower substrate having a first surface and having a first lower region, a second lower region, and a third lower region which are provided on the first surface, an upper substrate having a first surface disposed to face the first surface of the lower substrate, and having a plurality of first upper regions to correspond to the first lower region, a second upper region to correspond to the second lower region, and a third upper region which are provided on the first surface of the upper substrate, a first connection structure disposed to electrically connect the first lower region to the plurality of first upper regions, a second connection structure disposed to electrically connect the second lower region to the second upper region, and a third connection structure disposed to electrically connect the third lower region to an external semiconductor package structure.

The foregoing and/or other aspects and utilities of the inventive concept, may also be achieved by providing a method of forming an electronic device, the method including providing a lower substrate having a first surface and a first lower region provided on the first surface, forming a first lower connection structure on the first lower region, providing an upper substrate having a first surface disposed to face the first surface of the lower substrate and having a plurality of first upper regions provided on the first surface of the upper substrate, forming a plurality of first upper connection structures on the corresponding first upper regions, and forming a connection structure disposed between the first surfaces of the lower and upper substrates by processing the first lower connection structure and the plurality of first upper connection structures, to electrically connect the first lower region of the lower substrate to the plurality of first upper regions of the upper substrate.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIG. 1 is a plan view of an electronic device according to an embodiment of the inventive concept;

FIGS. 2A and 2B are plan views of parts of the electronic device of FIG. 1;

FIG. 3 is a longitudinal sectional view of a part of an electronic device according to an embodiment of the inventive concept;

FIG. 4 is a longitudinal sectional view of an electronic device according to an embodiment of the inventive concept;

FIG. 5 is a longitudinal sectional view of an electronic device according to an embodiment of the inventive concept;

FIG. 6 is a longitudinal sectional view of an electronic device according to an embodiment of the inventive concept;

FIGS. 7A to 10 are plan views of a part of an electronic device according to an embodiment of the inventive concept;

FIGS. 11A and 11B are longitudinal sectional views of a lower body according to an embodiment of the inventive concept;

FIGS. 12A and 12B are longitudinal sectional views of an upper body according to an embodiment of the inventive concept;

FIGS. 13A and 13B are longitudinal sectional views of an electronic device according to an embodiment of the inventive concept;

FIG. 14 is a longitudinal sectional view of an electronic device according to an embodiment of the inventive concept;

FIG. 15 is a diagram illustrating a configuration of an electronic system employing an electronic device according to an embodiment of the inventive concept; and

FIG. 16 is a block diagram of a system employing an electronic device according to an embodiment of the inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures. In the drawings, the sizes and relative sizes of layers and regions may be exaggerated for clarity.

It will be understood that when an element or layer is referred to as being “on,” “connected to” or “coupled with” another element or layer, it can be directly on, connected or coupled to the other element or layer or intervening elements or layers may be present. In contrast, when an element is referred to as being “directly on,” “directly connected to” or “directly coupled with” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “electrically connected” and/or “electrically insulated” used in this specification, specify “directly connected or insulated”.

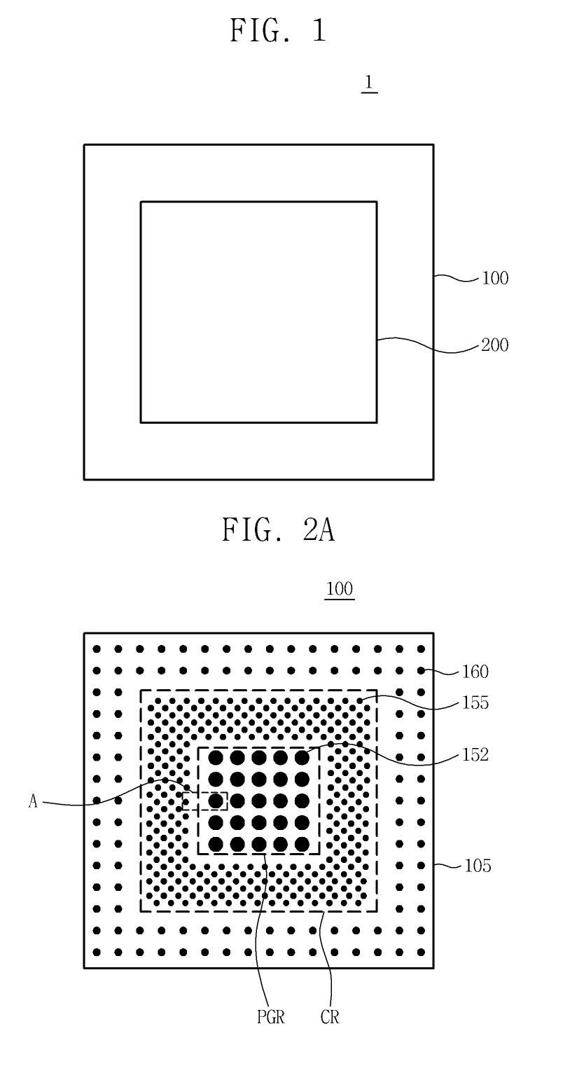

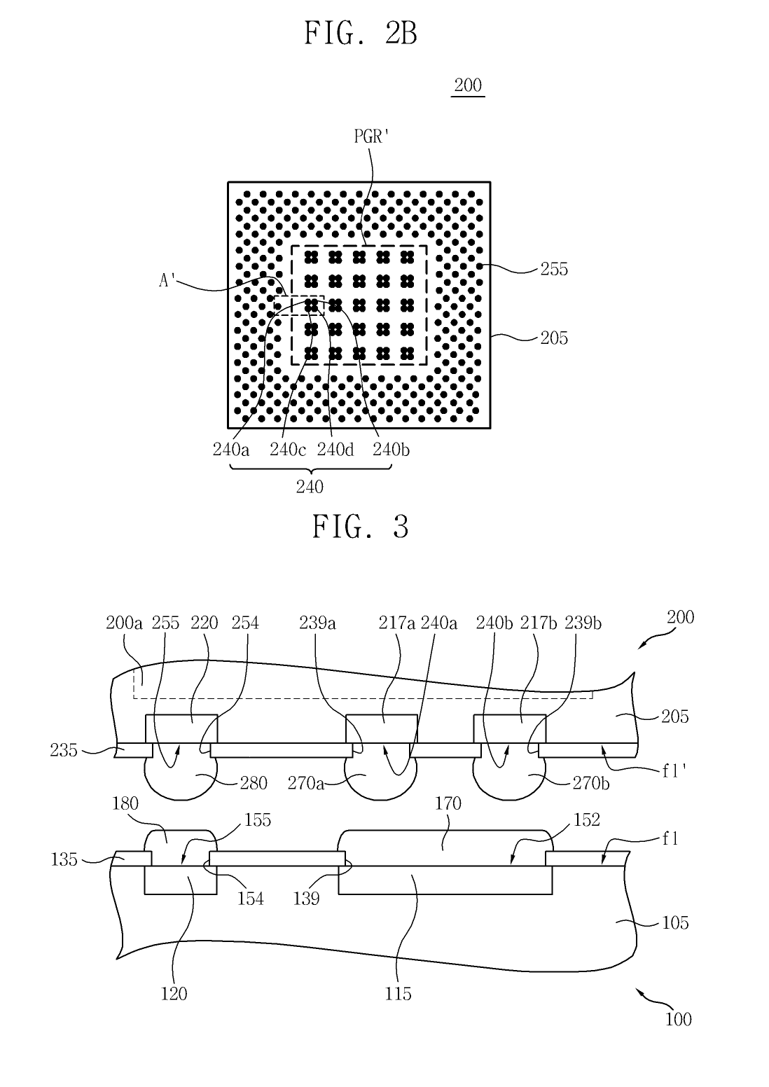

FIG. 1 is a plan view of an electronic device 1 according to an embodiment of the inventive concept, FIG. 2A is a plan view of a lower body constituting the electronic device 1 of FIG. 1, and FIG. 2B is a plan view of an upper body constituting the electronic device 1 of FIG.

Referring to FIG. 1, the electronic device 1 may include a lower body 100 and an upper body 200. The lower body 100 may be electrically connected to the upper body 200. The lower body 100 may have a larger flat area than the upper body 200.

Referring to FIGS. 1 and 2A, the lower body 100 may include a lower substrate 105. The lower substrate 105 may be a printed circuit board (PCB) or package substrate. First lower regions 152 may be provided in a first region PGR on a first surface of the lower substrate 105. Each of the first lower regions 152 may be a land region for ground or power.

Second lower regions 155 may be provided in a second region CR on the first surface of the lower substrate 105. The second lower regions 155 may be land regions for input/output (I/O) signals. Each second lower region 155 may have a smaller flat area than each first lower region 152. That is, one second lower region 155 may have a smaller width than one first lower region 152.

The first region PGR in which the first lower regions 152 are disposed may be disposed in a central portion of the lower substrate 105, and the second region CR in which the second lower regions 155 are disposed may be disposed to surround the first region PGR.

Third lower regions 160 are provided on an edge region of the lower substrate 105. The third lower regions 160 may be land regions for electrical connection with another package.

Here, the electronic device 1 may be referred to as a package (semiconductor package or semiconductor chip structure). The electronic device 1 may be electrically connected to the package, the semiconductor package structure, the semiconductor chip structure, an electronic apparatus, etc., through the third lower regions 160.

Referring to FIGS. 1 and 2B, the upper body 200 may include an upper substrate 205. The upper substrate 205 may include a semiconductor chip 200a as illustrated in FIG. 3. The upper substrate 205 may include at least one of a microprocessor and a logic device. For example, the upper substrate 105 may include a semiconductor chip including a central processing unit (CPU) or a control chip including a logic device.

First upper regions 240a to 240d are provided to be spaced apart from each other in a first region PGR′ on a first surface of the upper substrate 205. Here, the first surface of the upper substrate 205 may face the first surface of the lower substrate 105. The first region PGR′ of the upper substrate 205 may correspond to the first region PGR of the lower substrate 105. The plurality of first upper regions 240a to 240d may correspond to one first lower region 152.

FIGS. 2A and 2B illustrate that four first upper regions 240a to 240d correspond to one first lower region 152, but the inventive concept is not limited thereto. For example, the one first lower region 152 may correspond to two, three, five, or more first upper regions.

Second upper regions 255 may be provided on the first surface (f1′ of FIG. 3) of the upper substrate 205. The second upper regions 255 may correspond to the second lower regions 155 of the lower substrate 105.

Hereinafter, an electrical connection relationship between the lower body 100 and the upper body 200 will be described with reference to FIGS. 3 through 6 which illustrate longitudinal sectional views of regions indicated by “A” of FIG. 2A and “A”′ of FIG. 2B.

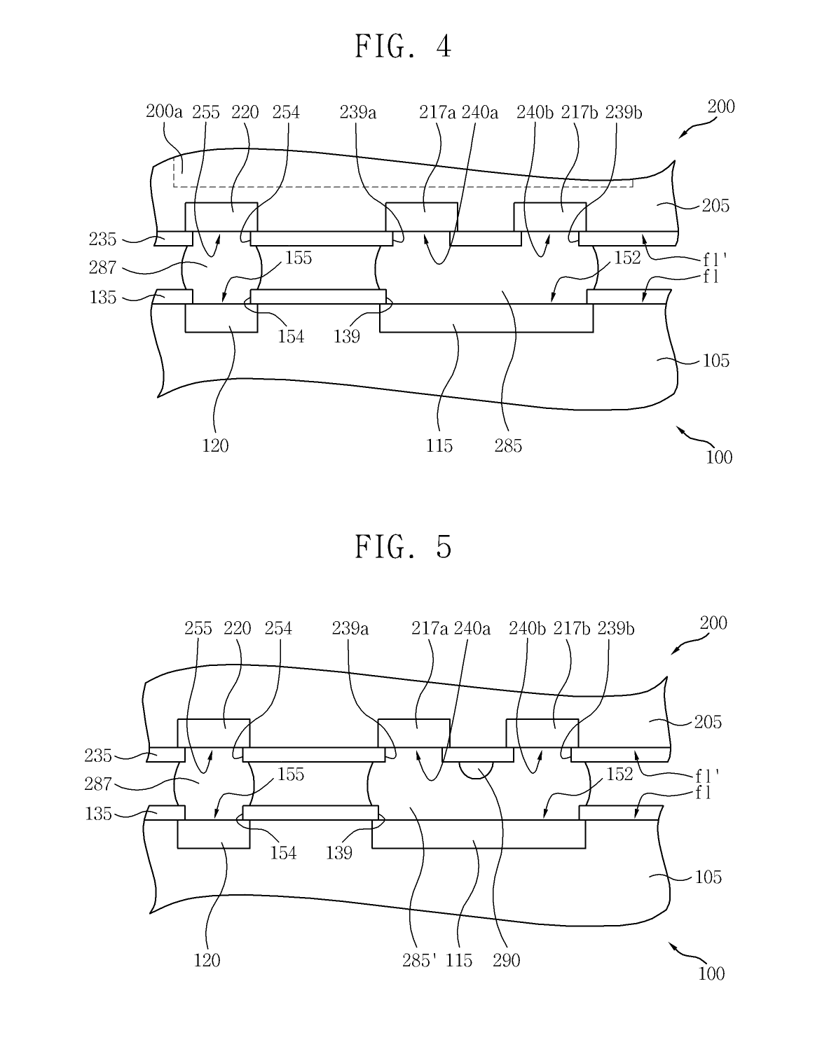

FIG. 3 is a longitudinal sectional view of the electronic device 1 before the lower body 100 is electrically connected to the upper body 200. The upper body 200 may include a semiconductor chip 200a and a circuit or conductive line formed therein to electrically connect the semiconductor chip 200a and the first and second upper regions 240 and 255. Since the circuit or conductive line is well known, detail descriptions thereof will be omitted. It is also possible that the semiconductor chip 200a may be installed in the lower substrate 100 instead of the upper substrate 205. In this case, a circuit or conductive line may be formed in the lower substrate 100 to electrically connect the semiconductor chip 200a to the first lower region 152 and/or second lower region 155. It is also possible that the semiconductor chip 200a may be installed in both the lower body 100 and the upper body 200. FIGS. 4, 5, and 6 are longitudinal sectional views of the electronic device 1 in which the lower body 100 is electrically connected to the upper body 200.

Referring to FIGS. 2A, 2B, and 3, a first lower conductive pattern 115 and a second lower conductive pattern 120 may be provided on the first surface f1 of the lower substrate 105. The first lower conductive pattern 115 may be a conductive pattern as one or more power/ground terminals connected between the semiconductor chip 200a and at least one of the lower body 100, the another package, or external device. The second lower conductive pattern 120 may be a conductive pattern as one or more I/O terminals to transmit or receive I/O signals (or data) between the semiconductor chip 200a and at least one of the lower body 100, the another package, or external device.

A first lower insulating layer 135 which is formed on the first surface f1 of the lower substrate 105 and includes a first lower opening 139 exposing the first lower conductive pattern 115, and a second lower opening 154 exposing the second lower conductive pattern 120 may be provided. The first lower insulating layer 135 may include a photo sensitive solder resist material.

A region of the first lower conductive pattern 115 which is exposed by the first lower opening 139 is defined as a first lower region or a first lower land region 152. A region of the second lower conductive pattern 120 which is exposed by the second lower opening 154 is defined as a second lower region or a second lower land region 155.

A first lower connection structure 170 may be provided on the first lower region or the first lower land region 152. The first lower connection structure 170 may include a solder material. A second lower connection structure 180 may be provided on the second lower region or the second lower land region 155. The second lower connection structure 180 may include a solder material. The first and second lower connection structures 170 and 180 may be formed of the same material. The first and second lower connection structures 170 and 180 may have upper surfaces which are positioned at substantially the same level.

First upper conductive patterns 217a and 217b and a second upper conductive pattern 220 may be provided on the first surface f1′ of the upper substrate 205. The first upper conductive patterns 217a and 217b may be conductive patterns for power/ground. The second upper conductive pattern 220 may be a conductive pattern for the I/O signals.

A first upper insulating layer 235 which is formed on the first surface f1′ of the upper substrate 205 and includes first upper openings 239a and 239b exposing the first upper conductive patterns 217a and 217b, and a second upper opening 254 exposing the second upper conductive pattern 220 may be provided. The first upper insulating layer 235 may include a photo sensitive solder resist material.

Regions of the first upper conductive patterns 217a and 217b which are exposed by the first upper openings 239a and 239b are defined as first upper regions or first upper land regions 240a and 240b, and a region of the second upper conductive pattern 220 which is exposed by the second upper opening 254 is defined as the a second upper region or a second upper land region 255.

First upper connection structures 270a and 270b may be provided on the first upper regions or the first upper land regions 240a and 240b. The first upper connection structures 270a and 270b may include solder materials. A second upper connection structure 280 may be provided on the second upper region or the second upper land region 255. The second upper connection structure 280 may include a solder material. The first and second upper connection structures 270a, 270b, and 280 may be formed of the same material.

Now, structures of various shapes in which the lower body 100 and the upper body 200 are physically and electrically connected will be described with reference to FIGS. 4 to 6.

First, referring to FIGS. 2A, 2B, and 4, the first lower connection structure 170 and the plurality of first upper connection structures 270a and 270b may be physically and electrically connected to form a first connection structure 285. Accordingly, one first lower land region 152 and the plurality of first upper land regions 240a and 240b may be electrically connected by the first connection structure 285.

The second lower connection structure 180 and the second upper connection structure 280 may be physically and electrically connected to form a second connection structure 287. Accordingly, one second lower land region 155 and one second upper land region 255 may be electrically connected by the second connection structure 287.

One side of the first connection structure 285 may be in contact with the first lower land region 152 having a relatively large flat area, and the other side of the first connection structure 285 may be in contact with the plurality of first upper land regions 240a and 240b. Each of the first upper land regions 240a and 240b may have substantially the same plane as the second upper land region 255. Accordingly, the first connection structure 285 may have a larger flat area than the second connection structure 287. In addition, the first connection structure 285 may have a larger width than the second connection structure 287. The first connection structure 285 may have a larger volume than the second connection structure 287.

The first connection structure 285 may be formed by physically coupling the first lower connection structure 170 and the plurality of first upper connection structures 270a and 270b using a solder reflow process. The second connection structure 287 may be formed by physically coupling the second lower connection structure 180 and the second upper connection structure 280 using a solder reflow process.

Since the connection structures 170, 270a, 270b, 180, and 280 are formed of a solder material, the upper/lower connection structures 170, 270a, 270b, 180, and 280 may be melted and hardened by a solder reflow process to form the first and second connection structures 285 and 287.

The first connection structure 285 is formed between the first upper connection structures 270a and 270b so that a space between the first upper connection structures 270a and 270b may be completely filled by the first connection structure 285. However, the inventive concept is not limited thereto. For example, if the space between the first upper connection structures 270a and 270b is large, when the first upper connection structures 270a and 270b are physically coupled to the first lower connection structure 170 by a solder reflow process, a first connection structure 285′ may be formed, while a space 290 is formed between the first upper land regions 240a and 240b, as illustrated in FIG. 5.

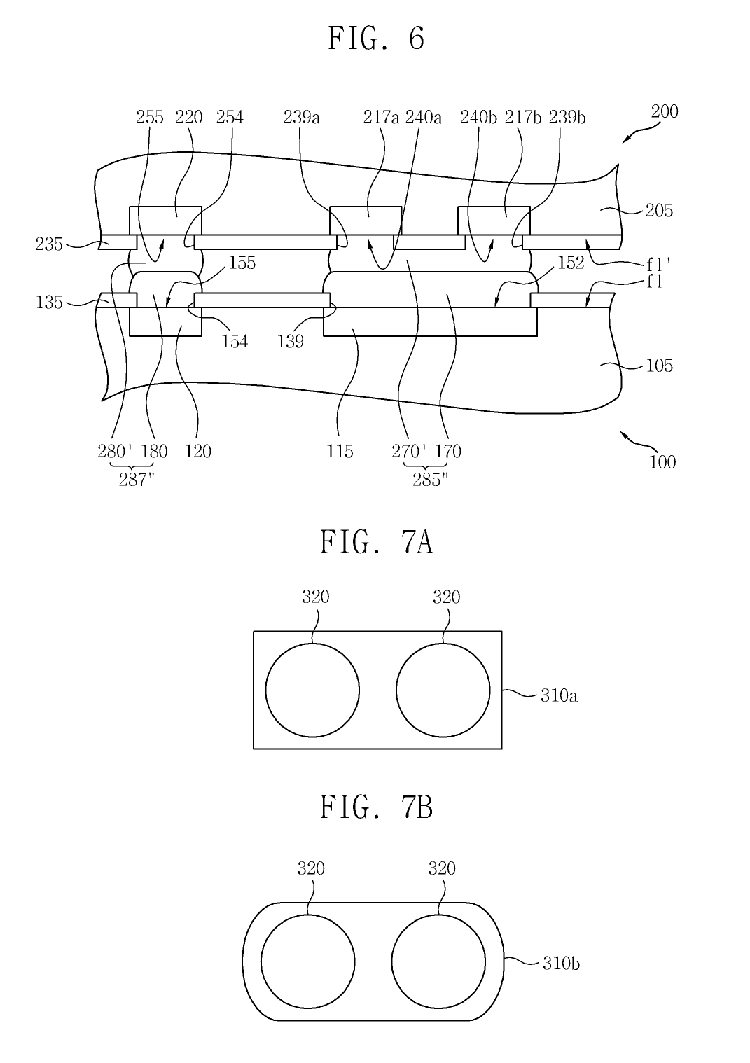

The first connection structure 285 may be modified as illustrated in FIG. 6. For example, among the connection structures 170, 270a, 270b, 180, and 280, when the first and second lower connection structures 170 and 180 are formed of a conductive material such as copper having a higher melting temperature than a solder material, and the first and second upper connection structures 270a, 270b, and 280 are formed of a solder material, the first and second upper connection structures 270a, 270b, and 280 may be physically and electrically connected to the first and second lower connection structures 170 and 180, while the first and second upper connection structures 270a, 270b, and 280 may be melted and hardened by a solder reflow process. A melted and hardened first upper connection structure 270′ and the first lower connection structure 170 may constitute a modified first connection structure 285′. A melted and hardened second upper connection structure 280′ and the second lower connection structure 180 may constitute a modified second connection structure 287″.

A single first lower land region 152 and the plurality of first upper land regions 240a, 240b, 240c, and 240d may overlap. Here, the first lower land region 152 may be modified in various shapes, and the plurality of first upper land regions 240a, 240b, 240c, and 240d which overlap the one first lower land region 152 may also be disposed in various types.

Hereinafter, the first lower land region modified in various shapes and the first upper land regions disposed in various types will be described with reference to FIGS. 7A through 10.

FIGS. 7A through 10 are plan views showing only a first lower land region and first upper land regions which overlap the first lower land region for the convenience of understanding the inventive concept. Accordingly, it may be understood that a first lower land region and a plurality of first upper land regions which will be described later are electrically connected by the first connection structures 285, 285′, and 285″ as described in FIGS. 4 through 6.

Referring to FIG. 7A, a first lower land region 310a which has a rectangular or line shape on a plane may be provided. Alternatively, a first lower land region 310b which has an elliptical or line shape on a plane may be provided as illustrated in FIG. 7B. The first lower land regions 310a and 310b may overlap two first upper land regions 320.

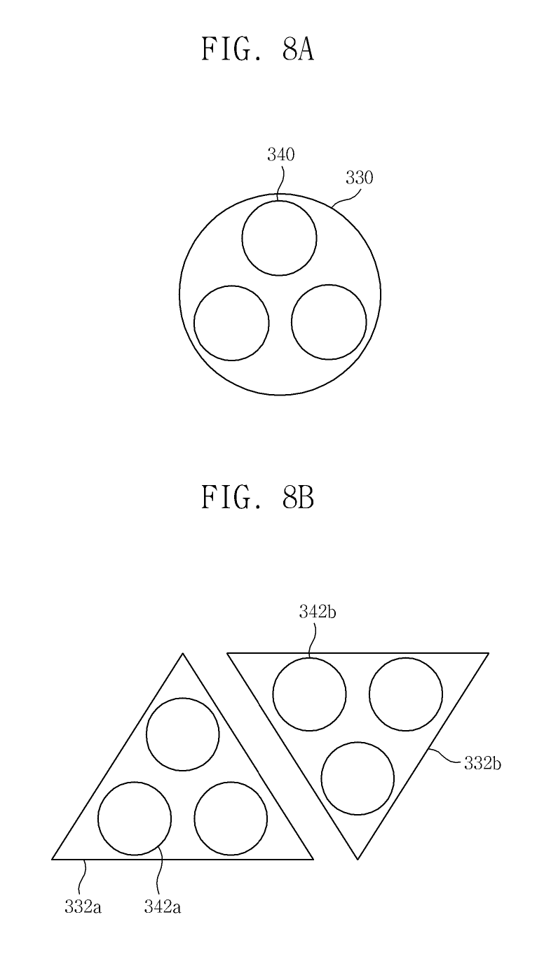

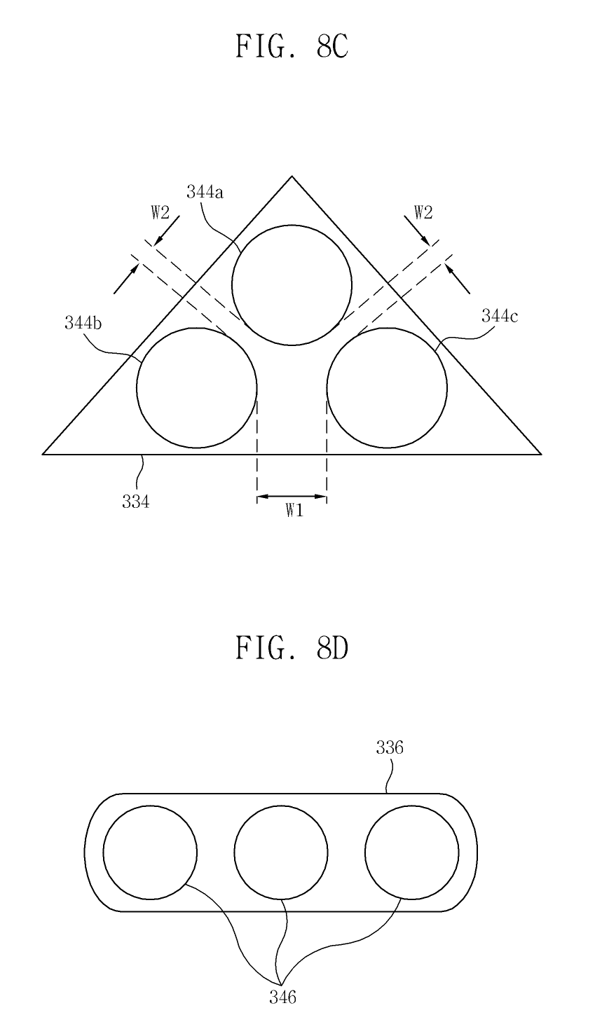

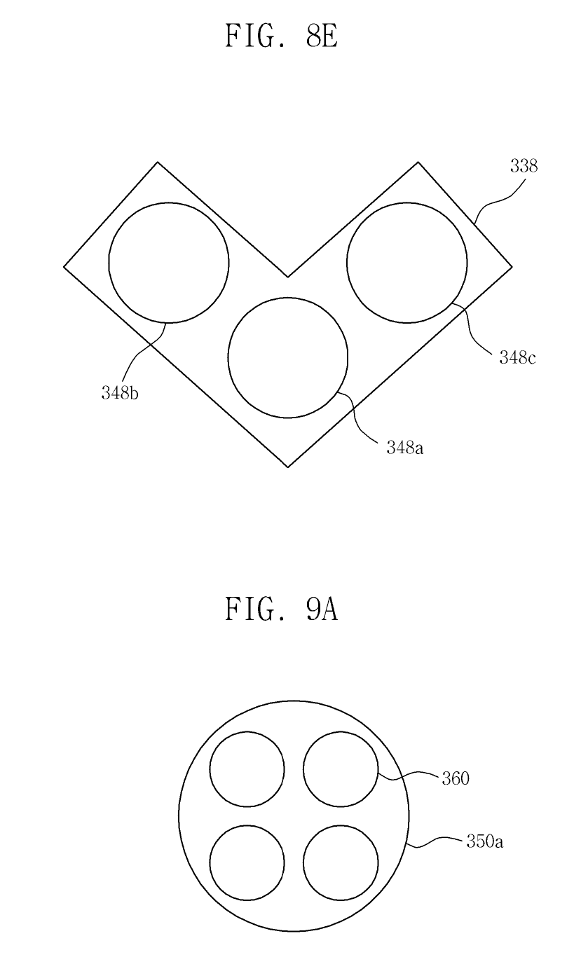

Referring to FIG. 8A, a first lower land region 330 which has a circular shape on a plane may be provided. Three first upper land regions 340 which overlap the circular-shaped first lower land region 330 may be provided.

Referring to FIG. 8B, a first lower land region 332a which has a triangular shape on a plane may be provided. Three or more first upper land regions 342a which overlap the triangular-shaped first lower land region 332a may be provided.

Also referring to FIG. 8B, another first lower land region 332b of an inverted triangular shape which is adjacent to and spaced apart from the triangular-shaped first lower land region 332a may be provided. Three or more other first upper land regions 342b which overlap the first lower land region 332b of the inverted triangular shape may be provided. Here, the first lower land region 332a of the triangular shape and the first lower land region 332b of the inverted triangular shape may be disposed so that one side of the first lower land region 332a of the triangular shape and one side of the first lower land region 332b of the inverted triangular shape are adjacent and parallel to each other. Accordingly, a flat area occupied by the first lower land regions 332a and 332b can be minimized.

Referring to FIG. 8C, a first lower land region 334 which has an isosceles triangular shape may be provided. Here, three first upper land regions 344a to 344c which overlap the first lower land region 334 may be provided.

A distance W2 between a first upper land region 344a and a second upper land region 344b of the first upper land regions 344a to 344c may be smaller than a distance W1 distance between the second upper land region 344b and a third upper land region 344c. A distance between the first upper land region 344a and the third upper land region 344c may be the same as the distance W2 distance between the first upper land region 344a and the second upper land region 344b. Accordingly, in a solder reflow process, a first upper connection structure in contact with the first upper land region 344a is coupled with first upper connection structures in contact with the second and third upper land regions 344b and 344c Since then, in the solder reflow process, a first upper connection structure in contact with the second upper land region 344b is coupled with a first upper connection structure in contact with the third upper land region 344c Accordingly, it is possible to prevent defects from occurring within a first connection structure 285 finally formed.

Referring to FIG. 8D, a first lower land region 336 which has a line shape on a plane may be provided. A plurality of first upper land regions 346 which are disposed along the shape of the first lower land region 336 may be provided.

A first lower land region 338 having a bent portion on a plane may be provided. For example, as illustrated in FIG. 8E, the first lower land region 338 may have a “V” shape. A plurality of first upper land regions 348a, 348b, and 348c which overlap the first lower land region 338 may be provided. Here, the first lower land region 338 may have a common portion and two portions extended from the common portion in different directions having an angle to form a bent portion or a “V” shape. The common area is disposed between the two extended portions. The first upper land region 348a is disposed on the common portion of the first lower land region 338, and the first upper land regions 348b and 348c may be disposed on the corresponding extended portions, respectively.

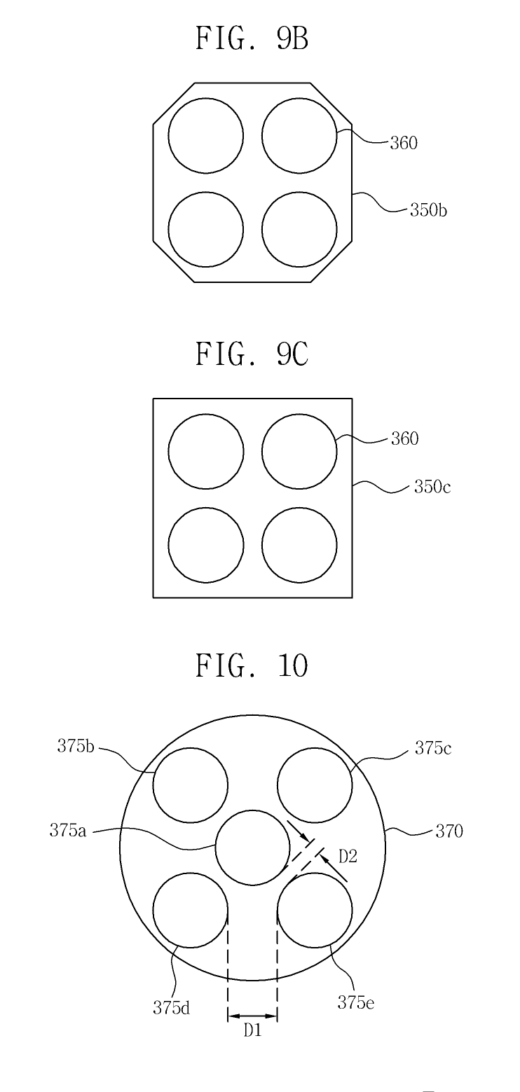

Referring to FIG. 9A, a first lower land region 350a having a circular shape on a plane, and four first upper land regions 360 overlapping the first lower land region 350a may be provided.

A first lower land region having a polygonal shape on a plane may be provided. For example, a first lower land region 350b which has an octagonal shape as illustrated in FIG. 9B or a first lower land region 350c which has a quadrangular shape as illustrated in FIG. 9C may be provided.

Referring to FIG. 10, a plurality of first upper land regions 375a 375b, 375c, 375c, and 375e may be provided. For example, a center land region 375a among the first upper land regions 375a, 375b, 375c, 375c, and 375e may be disposed at the center thereof, and the remaining land regions 375b, 375c, 375c, and 375e may be disposed around the center land region 375a. One first lower land region 370 which overlaps the first upper land regions 375a, 375b, 375c, 375c, and 375e may be provided. Here, the first lower land region 370 may have a circular shape as illustrated in FIG. 10, but the inventive concept is not limited thereto. For example, the first lower land region 370 may have a polygonal shape such as a quadrangular shape or an octagonal shape.

The remaining land regions 375b, 375c, 375c, and 375e may be spaced apart from each other by a distance D1. The center land region 375a is disposed and spaced apart from at least one of the remaining land regions 375b, 375c, 375c, and 375e by a distance D2. Here, the distance D1 may be greater than the distance D2. However, the present general inventive concept is not limited thereto. The distances D1 and D2 may vary.

The first upper land regions 375a 375b, 375c, 375c, and 375e may have areas with respect to an area or surface of the first lower land region 370. The areas of the first upper land regions 375a 375b, 375c, 375c, and 375e may be same. However, the present general inventive concept is not limited thereto. It is possible that the areas of the first upper land regions 375a 375b, 375c, 375c, and 375e may be different. It is also possible that the area of the center land region 375a may be different from the areas of the remaining land regions 375b, 375c, 375c, and 375e.

Although two, three, four, or five first upper land regions which overlap one first lower land region are illustrated as described above, the inventive concept is not limited thereto. For example, six or more first upper land regions may overlap one first lower land region.

In addition, although the first lower land region having various shapes such as a line, circular, elliptical, triangular, bent, quadrangular, or octagonal shape is illustrated as described above, the inventive concept is not limited thereto and may modify the first lower land region into various shapes.

According to the embodiments, an electronic device which includes a conductive connection structure to connect one lower land region and a plurality of upper land regions may be provided. In other words, one side of the connection structure is in contact with the one lower land region having a relatively large flat area, and the other side of the connection structure is in contact with the plurality of upper land regions having a relatively small flat area so that occurrence of defects such as cracks can be prevented in the connection structure. Accordingly, reliability and endurance of the semiconductor package employing the connection structure can be improved.

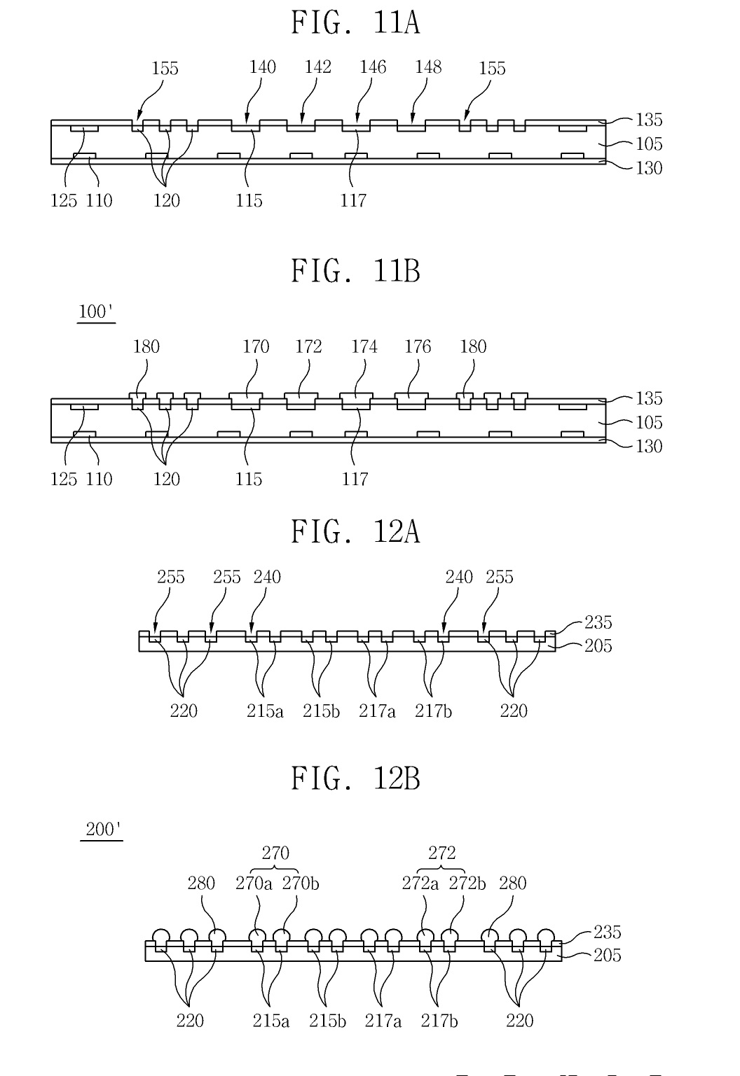

Now, a method of fabricating an electronic device according to an embodiment of the inventive concept will be described with reference to FIGS. 11A through 13B.

FIGS. 11A and 11B are longitudinal sectional views conceptually explaining a method of forming a lower body 100′, and FIGS. 12A and 12B are longitudinal sectional views conceptually explaining a method of forming an upper body 200′.

Referring to FIG. 11A, a lower substrate 105 which includes lower conductive patterns 115, 117, 120, and 125 on a first surface thereof, and conductive pads 110 on a second surface thereof facing the first surface may be prepared. The lower substrate 105 may include a multi-layered printed circuit board (PCB). For example, the lower substrate 105 may include a multi-layered PCB having two to eight internal wiring layers (not shown) which may be electrically connected to each other. Accordingly, the lower conductive patterns 115, 117, 120, and 125 may be electrically connected to the conductive pads 110 through vias and/or internal wirings (not shown) within the lower substrate 105.

Among the lower conductive patterns 115, 117, 120, and 125, the first lower conductive patterns 115 and 117 may be classified into a conductive pattern 115 for power and a conductive pattern 117 for ground. The second lower conductive patterns 120 may be conductive patterns for I/O signal transmission, and the third lower conductive patterns 125 may be conductive patterns for electrical connection with another semiconductor package structure. The lower conductive patterns 115, 117, 120, and 125 and the conductive pads 110 may be formed of a metal material such as copper. A protective insulating layer 130 may be provided on the second surface of the lower substrate 105 to cover the conductive pads 110.

A first lower insulating layer 135 may be formed to cover the first surface of the lower substrate 105. The first lower insulating layer 135 may include a photo sensitive solder resist material. The first lower insulating layer 135 may be patterned to form openings 140, 142, 146, 148, and 155 exposing the lower conductive patterns 115, 117, and 120. Among the openings 140, 142, 146, 148 and 155, regions of the first lower conductive patterns 115 and 117 exposed by first openings 140, 142, 146, and 148 may be defined as first PCB land regions or first lower land regions 140, 142, 146, and 148, and regions of the second lower conductive patterns 120 exposed by second openings 155 may be defined as second PCB land regions or second lower land regions 155.

Referring to FIG. 11B, first lower connection structures 170, 172, 174, and 176 may be formed on the first lower land regions 140, 142, 146, and 148, and second lower connection structures 180 may be formed on the second lower land regions 155 so that the lower body 100′ may be formed.

The first and second lower connection structures 170, 172, 174, 176, and 180 have flat areas of different sizes, but may be formed to have upper surfaces positioned at substantially the same level. For example, the first and second lower connection structures 170, 172, 174, 176, and 180 may be formed by forming structures for the first and second lower connection structures 170, 172, 174, 176, and 180, and planarizing the formed structures when heights of the formed structures are not uniform. Here, planarizing the formed structures may include applying pressure from tops to bottoms of the planarized structures until the structures have constant heights. The first and second lower connection structures 170, 172, 174, 176, and 180 may include a solder material.

The first and second lower connection structures 170, 172, 174, 176, and 180 may be formed using printing technology. For example, the first and second lower connection structures 170, 172, 174, 176, and 180 may be formed using printing technology such as ink jet printing technology and screen printing technology.

Referring to FIG. 12A, an upper substrate 205 which include first upper conductive patterns 215a, 215b, 217a, and 217b, and second upper conductive patterns 220 on a first surface f1′ thereof may be prepared. The upper substrate 205 may include a semiconductor chip having an integrated circuit. For example, the upper substrate 205 may include at least one of a microprocessor and a logic device. The upper substrate 205 may include a semiconductor chip including a CPU or a control chip having a logic device.

The first and second upper conductive patterns 215a, 215b, 217a, 217b, and 220 may include a metal material such as copper.

A first upper insulating layer 235 may be formed to cover the first surface of the upper substrate 205. The first upper insulating layer 235 may include a photo sensitive solder resist material. The first upper insulating layer 235 may be patterned to form first openings exposing the first upper conductive patterns 215a, 215b, 217a, and 217b, and second openings exposing the second upper conductive patterns 220. Regions of the first upper conductive patterns 215a, 215b, 217a, and 217b exposed by the first openings may be defined as first chip land regions or first upper land regions 240, and regions of the second upper conductive patterns 220 exposed by the second openings may be defined as second chip land regions or second upper land regions 255.

Referring to FIG. 12B, first upper connection structures 270 and 272 may be formed on the first upper land regions 240, and second upper connection structures 280 may be formed on the second upper land regions 255 so that the upper body 200′ may be formed. The first upper connection structures 270 and 272 may include structures 270a and 270b for power, and structures 272a and 272b for ground. The second upper connection structures 280 may be structures for I/O signal transmission.

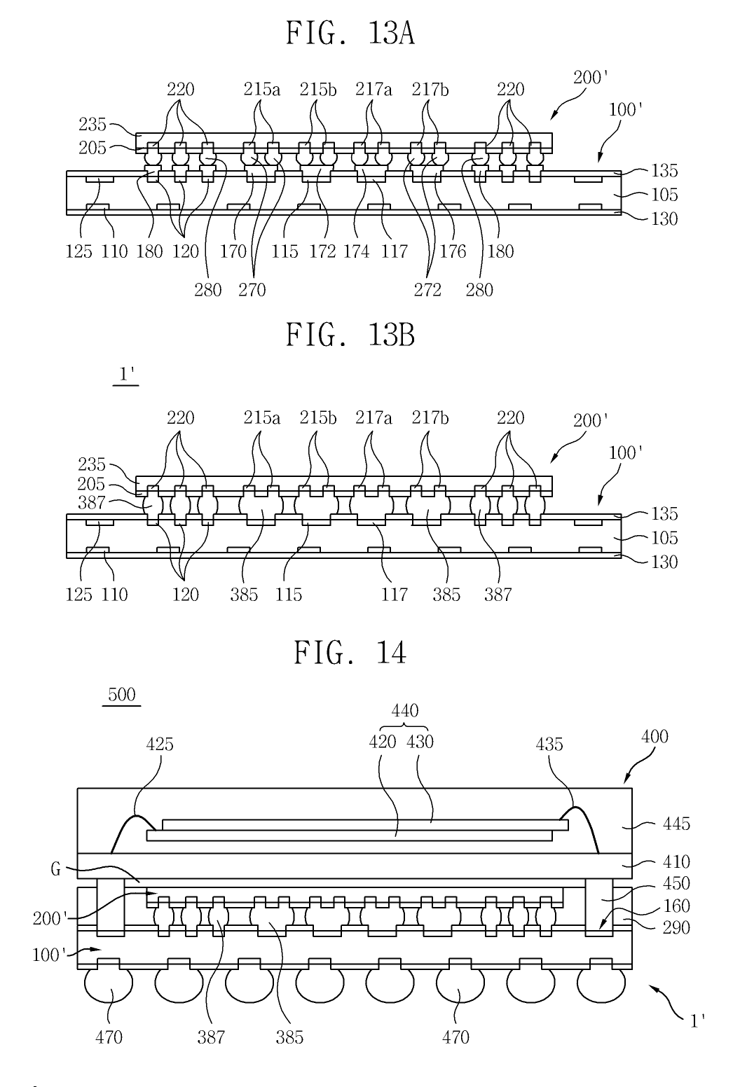

Referring to FIG. 13A, the lower body 100′ and the upper body 200′ may be disposed so that the first surface of the upper body 200′ faces the first surface of the lower body 100′.

Referring to FIG. 13B, the upper body 200′ including a semiconductor chip may be mounted on the lower body 100′ which may be used for a PCB. For example, a solder reflow process may be performed to physically and mechanically couple the upper and lower connection structures 170, 172, 174, 176, 270, 272, 180 and 280 so that first connection structures 385 and second connection structures 387 may be formed. Here, the first connection structures 385 may correspond to the first connection structures 285, 285′, and 285″ described in FIGS. 4 to 6, and the second connection structures 387 may correspond to the second connection structures 287 described in FIGS. 4 through 6.

Accordingly, a device 1′ in which the lower body 100′ and the upper body 200′ are physically and electrically connected may be formed as illustrated in FIG. 13B. Here, the device as in FIG. 13B may be defined as a first semiconductor package structure 1′.

An electronic device according to another embodiment of the inventive concept will be described with reference to FIG. 14.

Referring to FIG. 14, the first semiconductor package structure 1′ as in FIG. 13B may be provided. A lower molding compound 290 may be provided to fill an empty space between the upper body 200′ and the lower body 100′ in the semiconductor package structure 1′. Further, the lower molding compound 290 may cover the lower body 100′ and cover at least sidewalls of the upper body 200′. The first semiconductor package structure 1′ may include solder balls 470 electrically connected to the conductive pads 110 on the second surface of the lower substrate 105.

A second semiconductor package structure 400 may be provided on the first semiconductor package structure 1′. The first semiconductor package structure 1′ and the second semiconductor package structure 400 may be electrically connected by a conductive connection structure 450 for an inter-package connection so that a package-on-package (PoP) structure 500 may be provided.

The second package structure 400 may include a PCB 410, a semiconductor chip structure 440 on the PCB 410, and an upper molding compound 445 covering the PCB 410 and the semiconductor chip structure 440. The semiconductor chip structure 440 may include a plurality of stacked chips 420 and 430. The chips 420 and 430 and the PCB 410 may be electrically connected by connection structures 425 and 435 such as bonding wires.

The first package structure 1′ and the second package structure may have a gap G between the first package structure 1′ and the second package structure 400. The gap G may be maintained by the conductive connection structure 450 or an insulation material filled therein as a support. The lower molding compound 290 may be used as the insulation material to fill the gap G. However, the present general inventive concept is not limited thereto. A material different from the lower molding compound 290 can be used to fill the gap G. The gap G may not be entirely filled with the insulation material but may be filled in a plurality portions spaced apart from each other between the first package structure 1′ and the second package structure 400.

The PoP structure 500 is as illustrated above, but the inventive concept is not limited thereto. In other words, the embodiments which include a connection structure for electrically connecting one lower land region to a plurality of upper land regions may be applied to various devices and systems.

FIG. 15 is a schematic block diagram of an electronic system including one or more electronic devices according to an embodiment of the inventive concept.

Referring to FIG. 15, an electronic system 600 may include a controller 610, an I/O device 630, a storage device 620, and a bus structure 640. The controller 610 and the storage device 620 may be coupled to constitute a PoP. The controller 610 and/or the storage device 620 may include a device according to any one of the embodiments of the inventive concept described above.

The bus structure 640 may function to provide a path for mutual data transmission among the controller 610, the I/O device 630, and the storage device 620.

The controller 610 may include at least one of at least one microprocessor, a digital signal processor, a microcontroller, and logic devices which can perform functions similar thereto. The I/O device 630 may include at least one selected from a keypad, a keyboard, a display device, etc. The storage device 620 may store data and/or commands and the like executed by the controller 610.

The storage device 620 may include a volatile memory chip such as a dynamic random access memory (DRAM) and a static random access memory (SRAM), a non-volatile memory chip such as a flash memory, a phase change memory, a magnetic random access memory (MRAM), a resistive random access memory (RRAM) or a combination thereof.

In addition, a wired/wireless type interface (not shown) which transmits data to a communication network or receives data from the communication network may be further provided. For example, the interface may include an antenna, a wired/wireless transceiver, etc.

An application chipset, a camera image processor (CIS) and an I/O device may be further provided in the electronic system 600.

The electronic system 600 may be embodied by a mobile system, a personal computer, an industrial computer, a logic system which performs various functions, etc. For example, the mobile system may include any one of a personal digital assistant (PDA), a smart phone, a portable computer, a web tablet, a mobile phone, a wireless phone, a laptop computer, a memory card, a digital music system and an information transmission/reception system.

When the electronic system 600 is a wireless communicable apparatus, the electronic system 600 may be used in a communication system such as code division multiple access (CDMA), global system for mobile communication (GSM), North American digital cellular (NADC), enhanced-time division multiple access (E-TDMA), wideband code division multiple access (WCDMA), or CDMA2000.

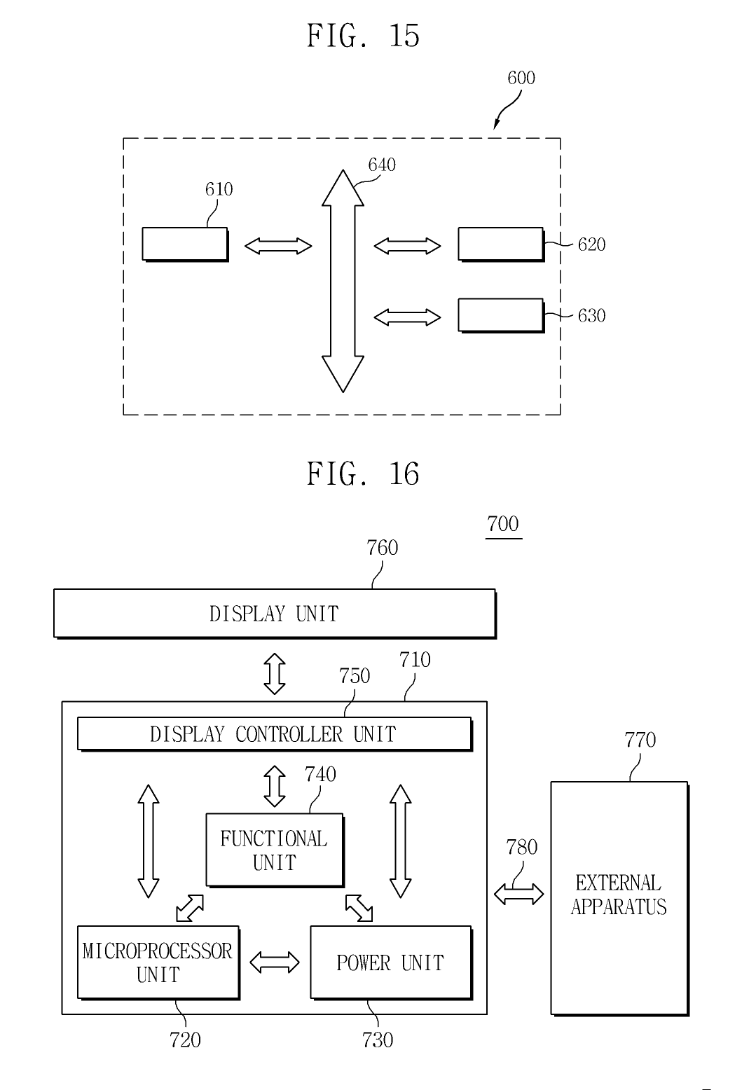

FIG. 16 is a block diagram of an electronic system 700 employing one or more electronic devices according to an embodiment of the inventive concept.

Referring to FIG. 16, the electronic system 700 may include a body 710, a micro processor unit 720, a power unit 730, a functional unit 740, and a display controller unit 750. The microprocessor unit 720 and/or the functional unit 740 may include a device according to any one of the embodiments of the inventive concept.

The body 710 may include a mother board formed of a PCB. The micro processor unit 720, the power unit 730, the functional unit 740, and the display controller unit 750 may be installed on the body 710. The display unit 760 may be disposed in the body 710 or on a surface of the body 710. For example, the display unit 760 may be disposed on the surface of the body 710 to display an image processed by the display controller unit 750.

The power unit 730 may serve to supply a predetermined voltage, which is supplied from an external battery (not shown) and then divided according to a required level of voltage, to the micro processor unit 720, the functional unit 740, and the display controller unit 750.

The micro processor unit 720 may receive the voltage from the power unit 730, and control the functional unit 740 and the display unit 760. The functional unit 740 may perform various functions of the electronic system 700. For example, when the electronic system 700 is a mobile phone, the functional unit 740 may include various components capable of performing a mobile function such as dialing, the output of an image to the display unit 760 and the output of a sound to a speaker by communication with an external apparatus 770, and when a camera is installed together within the electronic system 700, the functional unit 740 may serve as a camera image processor.

For example, when the electronic system 700 is connected to a memory card in order to increase capacity, the functional unit 740 may be a memory card controller. The functional unit 740 may send and/or receive signals to and/or from the external apparatus 770 through a wired/wireless communication unit 780. Further, when the electronic system 700 requires a universal serial bus (USB) in order to expand its function, the functional unit 740 may serve as an interface controller.

According to the embodiments of the inventive concept, a conductive connection structure which connects one lower land region provided on a PCB to a plurality of upper land regions provided on a semiconductor chip structure may be provided. Accordingly, occurrence of defects such as cracks can be suppressed in the connection structure for connecting the PCB to the semiconductor chip structure so that reliability and endurance of the connection structure can be improved, and the reliability of a semiconductor package, an electronic device and an electronic system employing the connection structure can be improved.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. An electronic device, comprising:
a package substrate having a first surface and having a first lower region and a second lower region provided on the first surface;
a semiconductor chip structure having a first surface disposed to face the first surface of the package substrate and having a plurality of first upper regions and a second upper region provided on the first surface of the semiconductor chip structure;
a first connection structure and a second connection structure disposed between the first surface of the package substrate and the first surface of the semiconductor chip structure,
wherein the first lower region is connected to the plurality of the first upper regions by the first connection structure,
wherein the second lower region is connected to the second upper region by the second connection structure.

2. The electronic device according to claim 1, wherein each of the plurality of first upper regions has a smaller flat area than the first lower region.

3. The electronic device according to claim 1, wherein:
the package substrate includes:
a lower conductive pattern provided on the first surface thereof, and
a lower insulating material layer configured to cover the first surface thereof and having a lower openings exposing a predetermined regions of the lower conductive pattern; and
the lower conductive pattern exposed by the lower openings are defined as the first and second lower regions.

4. The electronic device according to claim 1, wherein:
the semiconductor chip structure includes:
upper conductive patterns provided on the first surface thereof, and
an upper insulating material layer configured to cover the first surface thereof and having upper openings exposing the upper conductive patterns; and
the upper conductive patterns exposed by the upper openings are defined as the first and second upper regions.

5. The electronic device according to claim 1, wherein the first lower region has a larger flat area than the second lower region.

6. The electronic device according to claim 1, wherein the first connection structure has a larger width than the second connection structure.

7. The electronic device according to claim 1, wherein the package substrate has a larger flat area than the semiconductor chip structure.

8. The electronic device according to the claim 1, further comprising:
a semiconductor package structure provided on the package substrate to cover the semiconductor chip structure; and
a third connection structure configured to electrically connect the semiconductor package structure to the package substrate,
wherein the package substrate includes a third lower region provided on the first surface thereof to be spaced apart from the first and second lower regions, and the third lower region is electrically connected to the third connection structure.

9. The electronic device according to claim 1, wherein:
the package substrate comprises a printed circuit board (PCB) having a first printed circuit board (PCB) land region as the first lower region and a second PCB land region as the second lower region;
the semiconductor chip structure has a plurality of first chip land regions as the plurality of first upper regions and a second chip land region as the second upper region; and
the first connection structure is configured to electrically connect the first PCB land region and the plurality of first chip land regions.
the second connection structure configured to electrically connect the second PCB land region to the second chip land region.

10. The electronic device according to claim 1, wherein the first and second connection structures have different widths from each other.

11. The electronic device according to claim 9, wherein the first PCB land region includes a bending portion or any one of circular, elliptical, triangular, and polygonal shapes when viewed from a plan view.

12. A semiconductor package structure, comprising:
an electronic device as a first semiconductor package, the electronic device comprising:
a lower substrate having a first surface and a first lower region provided on the first surface,
an upper substrate having a first semiconductor chip and a first surface disposed to face the first surface of the lower substrate and having a plurality of first upper regions provided on the first surface of the upper substrate, and
a connection structure disposed between the first surfaces of the lower and upper substrates to electrically connect the first lower region to the plurality of first upper regions;
a second semiconductor package having a second semiconductor chip to be connected to the first semiconductor package; and
another connection structure to connect the second semiconductor package to another lower region of the first surface of the lower substrate.

13. The semiconductor package structure according to claim 12, further comprising:
a second connection structure disposed to connect a second lower region of the first surface of the lower region and a second upper region of the first surface of the upper substrate.

14. The semiconductor package structure according to claim 13, wherein the number of the first lower region of the lower substrate is different from the number of the plurality of the first upper regions, and the number of the second lower region is same as the number of the second upper region.

15. The semiconductor package structure according to claim 13, wherein an area of the first lower region of the lower substrate is larger than a sum of areas of the plurality of the first upper regions.

16. The semiconductor package structure according to claim 13, wherein the first connection structure, the second connection structure, and the another connection structure are disposed in order from a center portion of the lower substrate or the upper substrate.

17. The semiconductor package structure according to claim 12, wherein the first connection structure is a power transmission terminal, and the another connection structure is a signal or data transmission terminal.

18. The semiconductor package structure according to claim 12, wherein:
the first lower region comprises a plurality of sub-first lower regions;
each of the first upper regions comprises a plurality of sub-first upper regions; and
the connection structure comprises a plurality of sub-connection structures to connect each sub-first lower region to the plurality of sub-first upper regions.

19. The semiconductor package structure according to claim 18, wherein each of the sub-first lower regions has an area larger than a sum of areas of the plurality of sub-first upper regions.

20. An electronic device comprising:
a lower substrate having a first surface and having a first lower region, a second lower region, and a third lower region which are provided on the first surface,
an upper substrate having a first surface disposed to face the first surface of the lower substrate, and having a plurality of first upper regions to correspond to the first lower region, a second upper region to correspond to the second lower region, and a third upper region which are provided on the first surface of the upper substrate,
a first connection structure disposed to electrically connect the first lower region to the plurality of first upper regions;
a second connection structure disposed to electrically connect the second lower region to the second upper region; and
a third connection structure disposed to electrically connect the third lower region to an external semiconductor package structure.
